(19) United States
(12) Patent Application Publication
(10) Pub. No.: US 2002/0105095 A1
(43) Pub. Date: Aug. 8, 2002

(54) Semiconductor package having a substrate including a die-attach aperture and method for packaging a semiconductor die

(76) Inventors: Ki Wook Lee, Seoul (KR); Dae Keun Park, Namyangju-city (KR)

Correspondence Address: WEISS & MOY PC, 4204 NORTH BROWN AVENUE, SCOTTSDALE, AZ, 85251, US

(21) Appl. No.: 10/068,585

(22) Filed: Feb. 5, 2002

(30) Foreign Application Priority Data
Feb. 6, 2001 (KR) 2001-5602

(51) Int. Cl. H01L 23/18

(52) U.S. Cl. 257/783; 438/118; 438/125; 257/784

(57) ABSTRACT

A semiconductor package having a substrate including a die attach aperture and method for packaging a semiconductor die reduce or eliminate failures due to the “popcorn” effect caused by heating of water vapor during the manufacturing process. An aperture is provided in a substrate to permit die attach material to protrude to the outside of the semiconductor package, providing a path for the exit of water vapor from the die attach material during the manufacturing process. The popcorn effect is thereby eliminated, resulting in higher yields from the manufacturing process.

### FIELD OF THE INVENTION

The present invention relates generally to integrated circuit packaging and more specifically, to a method and assembly for packaging an integrated circuit to prevent de-lamination.

### BACKGROUND OF THE INVENTION

Semiconductor packages typically provide a hermitic package that completely protects a contained semiconductor from an external environment. Substrate carriers such as lead frame carriers, printed circuit boards and circuit tape have all been used to support one or more semiconductor dies in an enclosure.

Typically, a semiconductor die is attached to a substrate by a die attach material. However, the interface between the semiconductor die and the die attach material and the interface between the die attach material and the substrate can be easily damaged due to a difference in thermal coefficient of expansion between the materials.

A particular problem is generated by water remaining within the semiconductor package during the manufacturing process. The package is subjected to high temperatures during many of the manufacturing processes and is thereby vaporized. The vapor expands into any gaps or de-lamination in the die attach structure and accelerates the process of de-lamination (the so-called “popcorn” phenomenon). In extreme cases, the semiconductor die may crack, resulting in a broken package.

De-lamination, popcorn phenomena and cracking mainly occur in substrate-based packages such as lead frame, printed circuit board, circuit film and circuit tape type packages. In particular, problems are generated in the solder re-flow process wherein conductive balls are fused to lands of the substrate using temperatures exceeding 200 degrees centigrade. The problem is further exacerbated by a preceding baking process performed to remove water from the semiconductor package. During the baking process, a heated encapsulant or die attach material is expanded and can easily absorb water, as the molecular structure of the heated material is larger than that of water, permitting absorption of water. Also, at these temperatures, water is vaporized causing emission of the water (flow of steam) through the material.

The water inside the semiconductor package is removed by the baking process, but since the water vapor is blocked by the substrate, it does not flow out completely. The water that remains within the package is rapidly vaporized by the high temperature of the solder re-flow process, resulting in the above-described popcorn phenomenon, which causes the interface between the semiconductor die and the substrate to be damaged and crack the semiconductor die.

Therefore, it would be desirable to provide a semiconductor package and method for packaging a semiconductor die that eliminate the popcorn phenomenon.

### SUMMARY OF THE INVENTION

The above stated objectives are achieved in a semiconductor package and method for packaging a semiconductor die. The semiconductor package includes a semiconductor die, a die attach material and a substrate. An aperture is provided in the substrate to permit die attach material to flow through the aperture to the back side of the substrate. Water vapor may thereby pass through the die attach material to the outside of the package, reducing or eliminating the popcorn phenomenon.

### BRIEF DESCRIPTION OF THE DRAWINGS

FIG. 1 is a sectional view illustrating a semiconductor package according to an embodiment of the present invention; and

FIGS. 2A through 2I are cross-sectional views for explaining a method for manufacturing the semiconductor package of FIG. 1.

The invention, as well as a preferred mode of use and advantages thereof, will best be understood by reference to the following detailed description of illustrative embodiments when read in conjunction with the accompanying drawings, wherein like reference numerals indicate like parts throughout.

### DETAILED DESCRIPTION

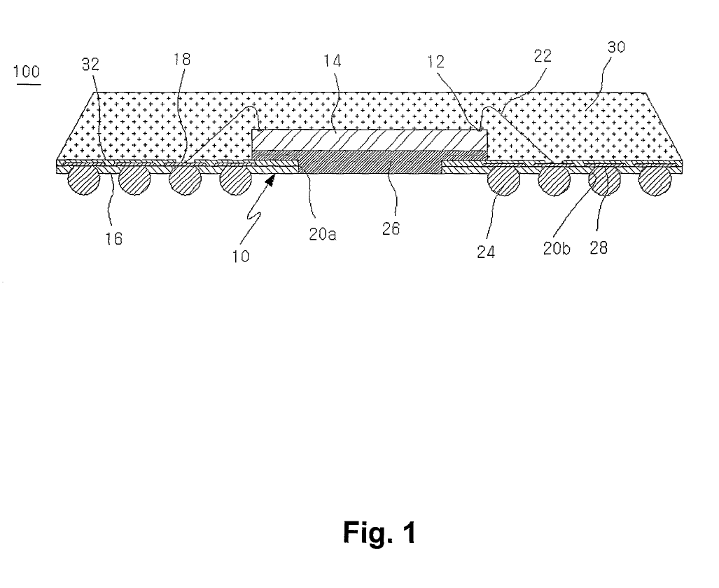

Referring to FIG. 1, a sectional view of a semiconductor package 100 according to an embodiment of the present invention is illustrated. A substrate 10, having an approximately planar surface including an insulating layer 16 of predetermined thickness formed at the bottom surface of substrate 16, is provided. An aperture 20a is formed through the center of insulating layer 16 and a plurality of electrically conductive patterns 18 are formed on the top surface of insulating layer 16 around the circumference of aperture 20a. A plurality of smaller apertures 20b are formed through insulating layer 16 around the circumference of aperture 20a. Small apertures 20b 20 are arrayed in rows and columns in their plan view (not shown).

Predetermined regions of electrically conductive patterns 18 are exposed at the bottom surface of insulating layer 16 by small apertures 20b, so that a plurality of lands 28 are formed. Insulating layer 16 may be any non-conductive material such as flexible tape, film, thermosetting resin or its equivalent.

The area (or size) of aperture 20a is smaller than that of a semiconductor die 14 as described below. It is preferable that aperture 20a has an area of approximately 50-90% of the area of the semiconductor die. The area of aperture 20a is thus restricted to allow the semiconductor die 14 to be placed in the range from the upper part of the aperture 20a to the circumference of semiconductor die 14. Conductive patterns 18 may be any conductive material such as aluminum (Al), copper (Cu), tungsten (W) or its equivalent.

A protective layer 32 can be applied over the entirety of conductive patterns 18 excluding the portions of conductive patterns to which a set of conductive wires 22 are connected. Protective layer 32 protects conductive patterns 18 from the external environment. In an alternative embodiment, protective layer 32 is not applied to the conductive patterns 18.

A die attach material 26 having a predetermined thickness is applied to aperture 20a and the top surface of the insulating layer 16 around the circumference of the aperture 20a. The die attach material 26 fills the entire aperture 20a and is applied up to a predetermined region of the top surface of protective layer 32 or insulating layer 16 around the circumference of aperture 20a. In the present embodiment, the area of die attach material 26 is approximately the same as that of semiconductor die 14. The bottom surface of die attach material 26 is flush with the bottom surface of substrate 10 (the bottom surface of insulating layer 16). The die attach material may be a conductive or nonconductive epoxy, adhesive or its equivalent.

The bottom surface of semiconductor die 14 is attached to die attach material 26, as provided. Semiconductor die 14 includes a plurality of bond pads 12 formed on top surface of semiconductor die 14. Bond pads 12 and conductive patterns 18 are electrically connected to each other by conductive wires 22. Conductive wire 22 may be any conductive material such as gold (Au), aluminum (Al), copper (Cu) or an equivalent.

The top surface of substrate 10, semiconductor die 14 and conductive wires 22 are encapsulated by an encapsulant 30 to protect them from the external environment. Encapsulant 30 may be an epoxy molding compound, “glob top” or an equivalent. A plurality of balls 24 (such as solder balls) are fused to each land 28 of substrate 10. Balls 24 serve to connect the semiconductor package of the present invention to an external device.

In the present embodiment, electrical signals from semiconductor die 14 are transmitted to an external device through bond pads 12, conductive wires 22, conductive patterns 18, lands 28 and balls 24. Electrical signals from the external device are transmitted to semiconductor die 14 through balls 24, lands 28, conductive patterns 18, conductive wires 22 and bond pads 12.

Since the area of the aperture 20a is similar to that of semiconductor die 14 and die attach material 26 fills the entirety of aperture 20a, water is easily emitted to the outside through die attach material 26, which has a molecular structure larger than that of the water. Accordingly, the emission of water is maximized and water is easily emitted to the outside through die attach material 26, thereby preventing the popcorn phenomenon and de-lamination between semiconductor die 14 and die attach material 26, resulting in prevention of a cracking of semiconductor die 14.

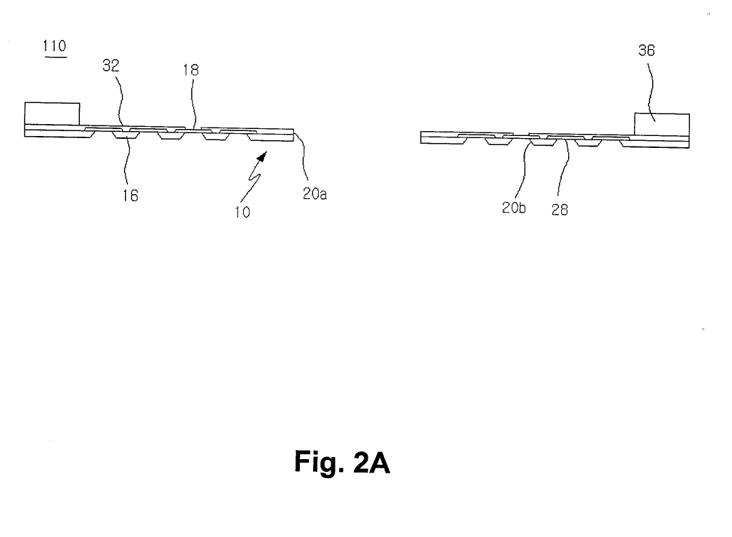

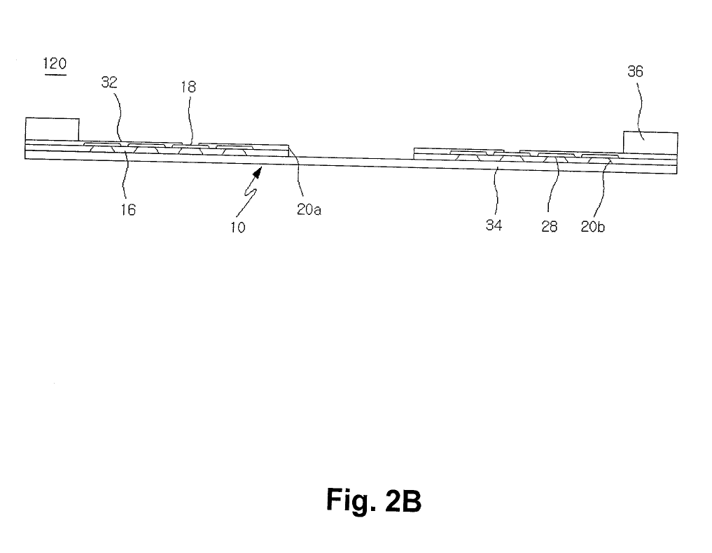

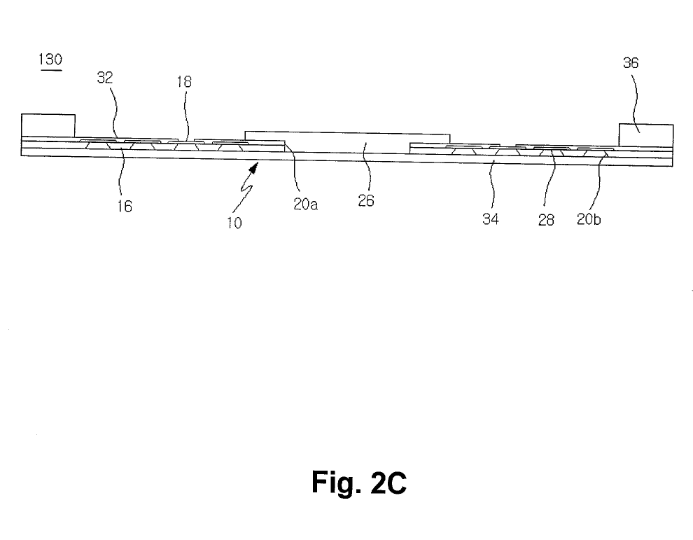

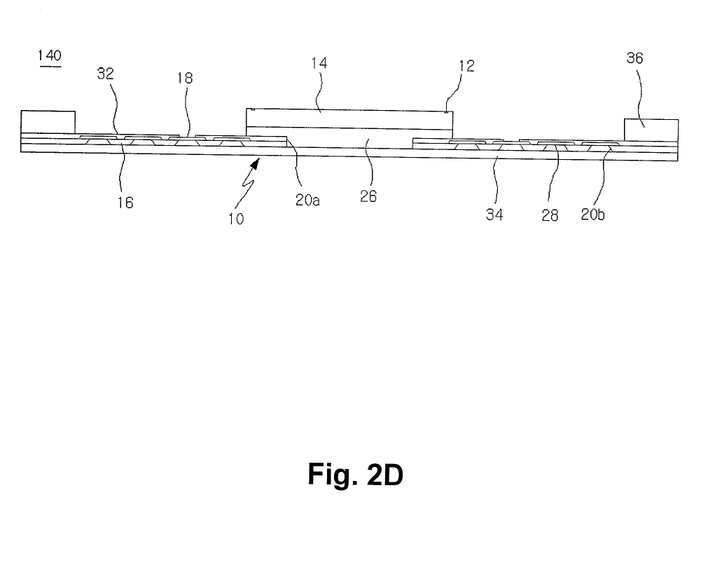

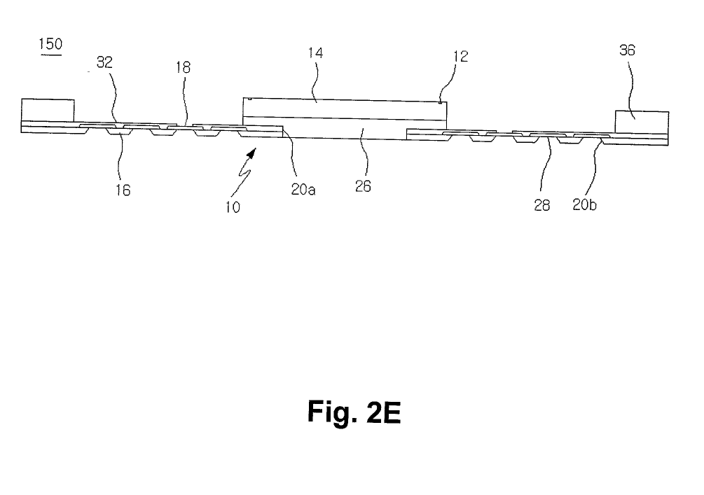

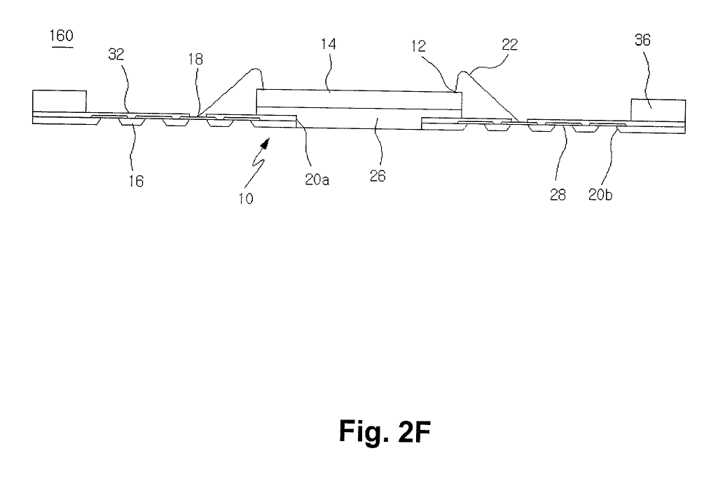

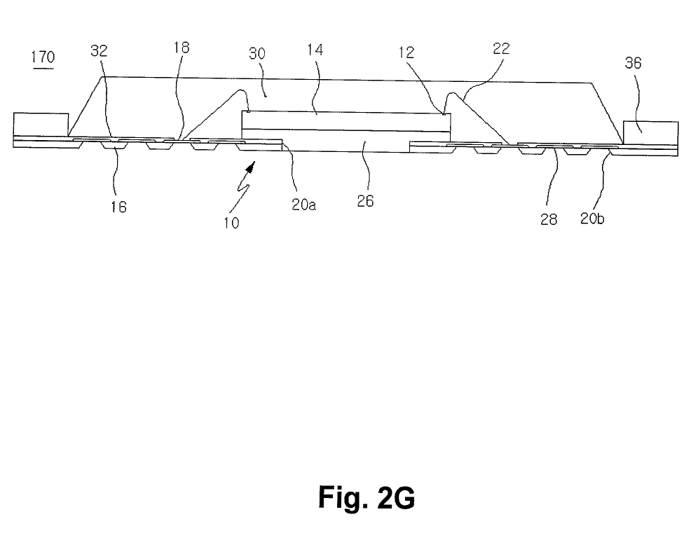

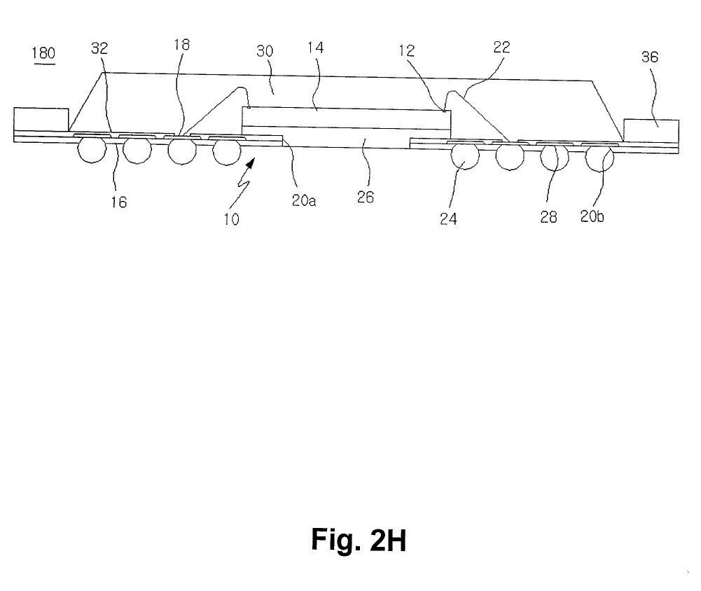

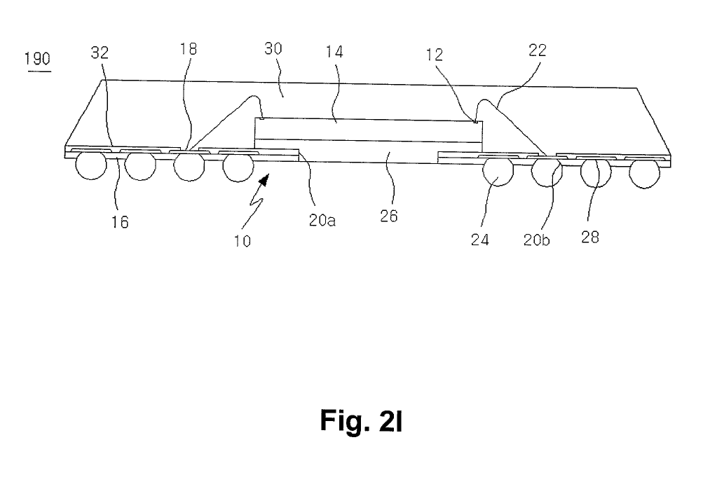

FIGS. 2A-2I are cross-sectional views that are used below to illustrate a method for manufacturing semiconductor package 100 of FIG. 1. Method according to embodiments of the present invention will be described in a stepwise manner with sequential reference to FIGS. 2A through 2I.

Referring FIG. 2A, a step 110 of providing a substrate 10 is illustrated. Substrate 10, including approximately planar insulating layer 16, aperture 20a having a predetermined size formed through the center of insulating layer 16, conductive patterns 18 formed on the top surface of insulating layer 16 around the circumference of the aperture 20a, small apertures 20b formed through insulating layer 16 around the circumference of aperture 20a, and lands 28 formed by exposing predetermined regions of conductive patterns 18 through the bottom surface of insulating layer 16 by small apertures 20b, is provided.

In the present embodiment, aperture 20a has an area of approximately 50-90% of the area of semiconductor die 14 (FIG. 1). A protective layer 32 can be applied, in accordance with an alternative embodiment of the present invention, over the entirety of conductive patterns 18 excluding areas to which conductive wires 22 (FIG. 1) are connected.

In an alternative embodiment, a carrier frame 36 can be coupled to the edge of the top surface of substrate 10, to prevent the bending of substrate 10. Accordingly, carrier frame 36 provides that substrate 10 will not be bent during the manufacturing of the semiconductor package.

Referring next to FIG. 2B, a tape attach step 120 is illustrated. The lower part of aperture 20a is covered with a tape 34 by applying tape 34 on the bottom surface of substrate 10.

Referring now to FIG. 2C, a die attach material 26 applying step 130 is illustrated. Die attach material 26 is applied to aperture 20a and a portion of the top surface of insulating layer 16 around the circumference of aperture 20a. Outflow of the die attach material 26 at the bottom surface of substrate 10 is prevented by tape 34. The bottom surface of die attach material 26 is thereby made flush with the bottom surface of insulating layer 16. The area of aperture 20a and the area of die attach material 26 formed on the upper part of substrate 10 are approximately the same as that of a semiconductor die 14 (FIG. 1).

Referring next to FIG. 2D, a semiconductor die 14 bonding step 140 is illustrated. A semiconductor die 14 having bond pads 12 formed on top surface thereof is bonded to die attach material 26. Die attach material 26 is hardened at a high temperature by a baking process after semiconductor die 14 is bonded. At this time, all of the water contained the die attach material 26 is emitted to the outside of the semiconductor package.

Referring now to FIG. 2E, a tape removing step 150 is illustrated. Tape 34, which was coupled to the bottom surface of the substrate 10 in step 120 is now removed. Tape 34 material may be any one of ultraviolet tape, adhesive tape or its equivalent. The adhesion capability of tape 34 is lost when ultraviolet radiation is applied. Thereafter, tape 34 is be easily detached.

Referring next to FIG. 2F, a wire bonding step 160 is illustrated. Bond pads 12 of semiconductor die 14 and conductive patterns 18 are electrically connected by conductive wires 22. Conductive wires 22 may be any one of aluminum (Al), gold (Au), copper (Cu) or an equivalent.

Next, referring to FIG. 2G, an encapsulating step 170 is illustrated. The top surface of substrate 10, semiconductor die 14 and conductive wires 22 are encapsulated by an encapsulant 30 in order to protect them from the external environment.

Now, referring to FIG. 2H, a ball fusing step 180 is illustrated. Balls 24 are fused to each land 28 of substrate 10. Conductive ball 24 serves to connect the semiconductor package to an external device.

Finally, referring to FIG. 2I, a singulation step 190 is illustrated. Carrier frame 36 (FIG. 2H) located at the edge of the top surface of substrate 10 is removed. Carrier frame 36 is removed by cutting substrate 10 around at the circumference of encapsulant 30. Carrier frame 36 serves to prevent the bending of the substrate 10 and ease handling of the semiconductor package. As bending is prevented by encapsulant 30 after the forming of encapsulant 30 and wherein carrier frame 36 is not required in the completed semiconductor package, carrier frame 36 may be removed.

Therefore, in the methods for manufacturing the semiconductor package according to the present invention, water existing between semiconductor die 14 and die attach material 26 is rapidly emitted to the outside through aperture 20a. Although aperture 20a is sealed by die attach material 26, the water can also be easily emitted to the outside through aperture 20a and die attach material 26 owing to the large size of aperture 20a.

Since the molecular structure of the die attach material 26 is larger than that of the water, the water can easily emitted to the outside. Even in the case where the pressure and load of encapsulant 30 is concentrated on aperture 20a of substrate 10 during the encapsulating step, no cracks of the semiconductor die 14 occur, because hardened die attach material 26 fills the entire aperture 20a. Since the semiconductor die 14 is strongly supported by the die attach material 26 filling aperture 20a, semiconductor die 14 does not crack while the pressure and load of the encapsulant 30 is concentrated on aperture 20a and the center of the bottom surface of semiconductor die 14.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

What is claimed is:

1. A semiconductor package, comprising
a semiconductor die;
a substrate defining an aperture formed through the center of the substrate from a top side to a bottom side of the substrate;
a die attach material applied within the aperture defined by the substrate and on the top side of the substrate between the semiconductor die and the substrate for attaching the semiconductor die to the substrate, and wherein the die attach material protrudes through the aperture to the bottom side of the substrate whereby water vapor can be emitted during the manufacturing of the semiconductor package.

2. The semiconductor package of claim 1, wherein the substrate further comprises a substantially planar insulating layer and a plurality of conductive patterns formed on the top surface of the insulating layer and located at the circumference of the aperture, whereby electrical connections of the semiconductor die are connected to lands near the periphery of the semiconductor package.

3. The semiconductor package of claim 2, wherein the insulating layer defines a plurality of small apertures formed through the insulating layer at the circumference of the aperture forming a plurality of lands by exposing predetermined regions of the conductive patterns through the bottom surface of the insulating layer through the small apertures.

4. The semiconductor package of claim 3, wherein the semiconductor die includes a plurality of bond pads, and wherein the bond pads are electrically connected to the conductive patterns.

5. The semiconductor package of claim 4, further comprising an encapsulant formed on the top surface of the substrate, over the semiconductor die and the conductive wires in order to protect them from the external environment.

6. The semiconductor package of claim 5, further comprising a plurality of balls each fused to a land of the substrate.

7. The semiconductor package of claim 5, wherein a bottom surface of the die attach material is flush with a bottom surface of the substrate.

8. The semiconductor package of claim 5, wherein the aperture has an area within a range of 50-90% of the area of the semiconductor die.

9. The semiconductor package of claim 5, further comprising a protective layer applied to the entirety of the conductive patterns excluding portions where the conductive wires are connected.

10. The semiconductor package of claim 3, further comprising a plurality of balls each fused to a land of the substrate.

11. The semiconductor package of claim 1, further comprising an encapsulant formed on the top surface of the substrate, over the semiconductor die and the conductive wires in order to protect them from the external environment.

12. The semiconductor package of claim 1, wherein a bottom surface of the die attach material is flush with a bottom surface of the substrate.

13. The semiconductor package of claim 1, wherein the aperture has an area within a range of 50-90% of the area of the semiconductor die.

14. The semiconductor package of claim 1, further comprising a protective layer applied to the entirety of the conductive patterns excluding portions where the conductive wires are connected.

15. A semiconductor package comprising:
a substrate comprising an approximately planar insulating layer, a plurality of conductive patterns formed on the top surface of the insulating layer and located at the circumference of the aperture, a plurality of small apertures formed through the insulating layer and located at the circumference of the substrate, and a plurality of lands formed by exposing predetermined regions of the conductive patterns through the bottom surface of the insulating layer through the small apertures, said substrate further comprising means for permitting die attach material to flow to a bottom side of the substrate;
a die attach material applied to the top surface of the insulating layer at the circumference of the aperture and within the die attach material flow means;
a semiconductor die having a plurality of bond pads attached to the die attach material;
a plurality of conductive wires electrically connecting the bond pads of the semiconductor die to the conductive patterns;
an encapsulant formed on the top surface of the substrate, over the semiconductor die and the conductive wires in order to protect them from the external environment; and
a plurality of balls each fused to a land of the substrate.

16. A method for manufacturing a semiconductor package, comprising:
providing a substrate comprising an approximately planar insulating layer defining an aperture having a predetermined size formed through the center of the insulating layer, a plurality of conductive patterns formed on the top surface of the insulating layer and located at the circumference of the aperture, a plurality of small apertures formed through the insulating layer and located at the circumference of the aperture, and a plurality of lands formed by exposing predetermined regions of the conductive patterns through the bottom surface of the insulating layer through the small apertures;
attaching a tape to a bottom surface of the substrate for covering the aperture of the substrate;
applying a die attach material within the aperture of the substrate and top surface of the insulating layer at the circumference of the aperture;
bonding a semiconductor die having a plurality of bond pads to the die attach material;
removing the tape attached to the bottom surface of the substrate;
connecting the bond pads of the semiconductor die to the conductive patterns with conductive wires;
applying an encapsulant to the top surface of the substrate, the semiconductor die and the conductive wires to protect them from the external environment; and
fusing a plurality of balls to each land of the substrate.

17. The method of claim 16, wherein providing the substrate provides a substrate having an area within the range of 50-90% of the area of the semiconductor die.

18. The method of claim 16, further comprising covering the conductive patterns, excluding portions to which the conductive wires are connected, with a protective layer.

19. The method of claim 16, further comprising attaching a carrier frame to an edge of the top surface of the substrate for preventing bending of the substrate.

20. The method of claim 19, further comprising removing the carrier frame by cutting the substrate near the circumference of the encapsulant, subsequent to fusing the balls.
